(19) United States
(12) Patent Application Publication
(10) Pub. No.: US 2015/0102329 A1
(43) Pub. Date: Apr. 16, 2015

(54) MASK FOR DEPOSITING THIN FILM, METHOD OF MANUFACTURING ORGANIC LIGHT EMITTING DIODE DISPLAY USING THE SAME, AND ORGANIC LIGHT EMITTING DIODE DISPLAY USING THE SAME

(71) Applicant: Samsung Display Co., Ltd., Yongin-City (KR)

(72) Inventor: Choong Ho LEE, Seoul (KR)

(21) Appl. No.: 14/512,281

(22) Filed: Oct. 10, 2014

(30) Foreign Application Priority Data
Oct. 11, 2013 (KR) 10-2013-0121463

(51) Int. Cl. H01L 51/00; B05C 21/00; H01L 51/52; H01L 51/56; H01L 27/32

(52) U.S. Cl. CPC H01L 51/0012; H01L 51/56; H01L 27/32; H01L 51/5203; B05C 21/005
USPC 257/40; 438/34; 118/504

(57) ABSTRACT

A mask for depositing a thin film according to an exemplary embodiment of the present invention includes: mask strips each including a plurality of pattern portions disposed end to end along one direction; and a frame on which the mask strips are positioned. Intervals between adjacent ends of adjacent pattern portions differ from each other according to distance from a predetermined location, thereby providing an organic light emitting diode display having a more uniform quality.

### CROSS-REFERENCE TO RELATED APPLICATION

This application claims priority to, and the benefit of, Korean Patent Application No. 10-2013-0121463 filed in the Korean Intellectual Property Office on Oct. 11, 2013, the entire contents of which are incorporated herein by reference.

### BACKGROUND

(a) Field

Embodiments of the present invention relate generally to organic light emitting diode displays. More specifically, embodiments of the present invention relate to a mask for depositing a thin film, a method of manufacturing an organic light emitting diode display using the same, and an organic light emitting diode display using the same.

(b) Description of the Related Art

A display device is a device displaying an image, one display utilizing such a device being an organic light emitting diode display.

The organic light emitting diode display has a self light emitting characteristic, and does not require a separate light source, unlike a liquid crystal display. Accordingly, that it is possible for the organic light emitting diode display to have decreased thickness and weight relative to liquid crystal displays. Further, the organic light emitting diode display exhibits high quality characteristics, such as low power consumption, high luminance, and a high response speed.

In order to form organic light emitting layers of red (R), green (G), and blue (B) on a substrate of the display, a metal mask may be used. In this case, an organic light emitting material of one color may be deposited, and then an organic light emitting material of another color may be formed while moving the metal mask by one pixel cell. Here, the metal mask is provided with an opening the size of one pixel.

However, in a case where the organic light emitting diode display is manufactured by using the aforementioned mask, the organic light emitting diode display with high resolution uses a mask pattern portion with a considerably small size, and shadows of considerable area are generated at both ends of the mask pattern portion, such that a limitation in accuracy is generated.

The above information disclosed in this Background section is only for enhancement of understanding of the background of the invention and therefore it may contain information that does not form the prior art that is already known in this country to a person of ordinary skill in the art.

### SUMMARY

Embodiments of the present invention have been made in an effort to provide an organic light emitting diode display which reduces shadow and achieves high resolution by adjusting an interval between pattern portions included in a mask.

An exemplary embodiment of the present invention provides a mask for depositing a thin film, including: mask strips each including a plurality of pattern portions disposed end to end along one direction; and a frame on which the mask strips are positioned. Intervals between adjacent ends of adjacent pattern portions differ from each other according to distance from a predetermined location.

A distance between the adjacent ends of adjacent pattern portions may decrease with distance from a center of the mask strip.

The number of mask strips may be plural.

The intervals between the adjacent pattern portions of each mask strip may be collectively positioned so as to be symmetric with respect to a center of the each mask strip.

Each mask strip may have a predetermined tension.

Each mask strip may include nickel or a nickel alloy.

Each mask strip of the plurality of mask strips may be welded to the frame.

Each mask strip of the plurality of mask strips may be affixed to the frame by laser welding.

The intervals between the adjacent pattern portions of each mask strip may be collectively positioned so as to be radially symmetric with respect to a center of the collective mask strips.

Another exemplary embodiment of the present invention provides a method of manufacturing an organic light emitting diode display, including: forming a first electrode; forming an organic light emitting layer on the first electrode by using a mask for depositing a thin film; and forming a second electrode on the organic light emitting layer. The mask for depositing the thin film includes: mask strips each including a plurality of pattern portions disposed end to end along one direction; and a frame on which the mask strips are positioned. Intervals between adjacent ends of adjacent pattern portions differ from each other according to distance from a predetermined location.

A distance between the adjacent ends of adjacent pattern portions may decrease with distance from a center of the mask strip.

The number of mask strips may be plural.

The intervals between the adjacent pattern portions of each mask strip may be collectively positioned so as to be symmetric with respect to a center of the each mask strip.

Each mask strip may have a predetermined tension.

Each mask strip may include nickel or a nickel alloy.

Each mask strip of the plurality of mask strips may be welded to the frame.

Each mask strip of the plurality of mask strips may be affixed to the frame by laser welding.

The intervals between the adjacent pattern portions of each mask strip can be collectively positioned so as to be radially symmetric with respect to a center of the collective mask strips.

An organic light emitting diode display according to the exemplary embodiment of the present invention may be manufactured by the aforementioned method of manufacturing the organic light emitting diode display.

When the aforementioned mask for the depositing the thin film is used, shadow is reduced so that it is possible to decrease deformation of a pattern of an opening, thereby providing an organic light emitting diode display with higher resolution.

### BRIEF DESCRIPTION OF THE DRAWINGS

FIG. 1 is a perspective view illustrating a mask for deposition according to an exemplary embodiment of the present invention.

FIG. 2 is a top plan view illustrating the mask for deposition according to the exemplary embodiment of the present invention.

FIG. 3 is a drawing illustrating a part of the mask according to the exemplary embodiment of the present invention.

FIG. 4 is a top plan view illustrating a mask for deposition according to another exemplary embodiment of the present invention.

FIG. 5 is a side view illustrating a deposition device using the mask for deposition according to the exemplary embodiment of the present invention.

FIG. 6 is a cross-sectional view illustrating an organic light emitting diode display according to an exemplary embodiment of the present invention.

FIG. 7 is a cross-sectional view illustrating the organic light emitting diode display according to the exemplary embodiment of the present invention.

### DETAILED DESCRIPTION OF THE EMBODIMENTS

In the following detailed description, only certain exemplary embodiments of the present invention have been shown and described, simply by way of illustration. As those skilled in the art would realize, the described embodiments may be modified in various different ways, all without departing from the spirit or scope of the present invention. The drawings and description are to be regarded as illustrative in nature and not restrictive. Like reference numerals designate like elements throughout the specification.

In describing each drawing, similar reference numerals are used for similar constituent elements. In the accompanying drawings, sizes of structures are enlarged compared to actual sizes for illustration for accuracy of the present invention. Accordingly, the drawings are not necessarily to scale. Although the terms first, second, third, etc. may be used herein to describe various constituent elements, they are not limited thereto. The terms are used only for the purpose of discriminating one constituent element from another constituent element. For example, a first constituent element may be called a second constituent element, and similarly, a second constituent element may be called a first constituent element without departing from the scope of the present invention. Singular expressions used herein include plural expressions unless they have definitely opposite meanings.

In the present application, it will be appreciated that terms “including” and “having” are intended to designate the existence of characteristics, numbers, steps, operations, constituent elements, and components described in the specification or a combination thereof, and do not exclude a possibility of the existence or addition of one or more other characteristics, numbers, steps, operations, constituent elements, and components, or a combination thereof in advance. It will be understood that when an element such as a layer, film, region, or substrate is referred to as being “on” another element, it can be directly on the other element or intervening elements may also be present. On the contrary, it will be understood that when an element such as a layer, film, region, or substrate is referred to as being “beneath” another element, it can be directly beneath the other element or intervening elements may also be present.

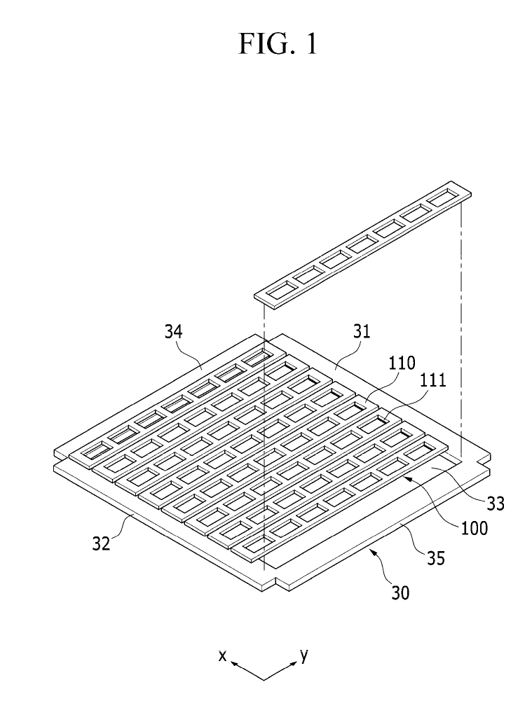

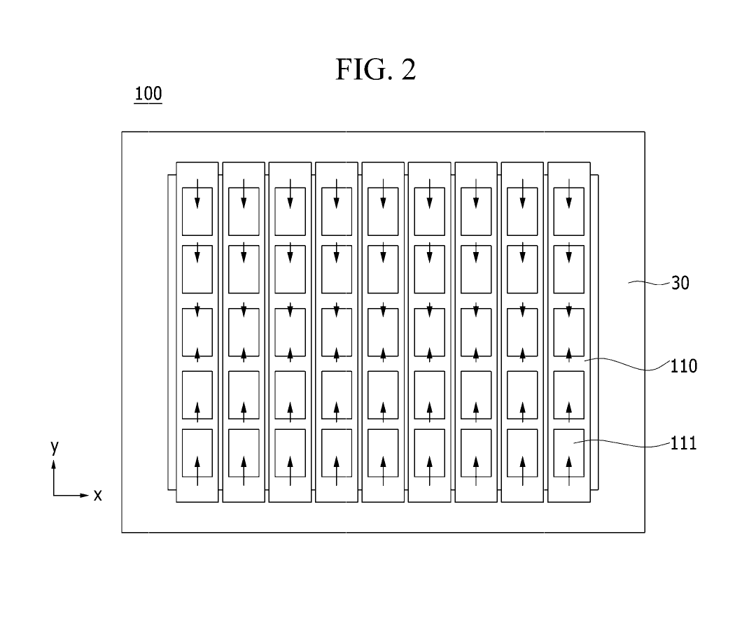

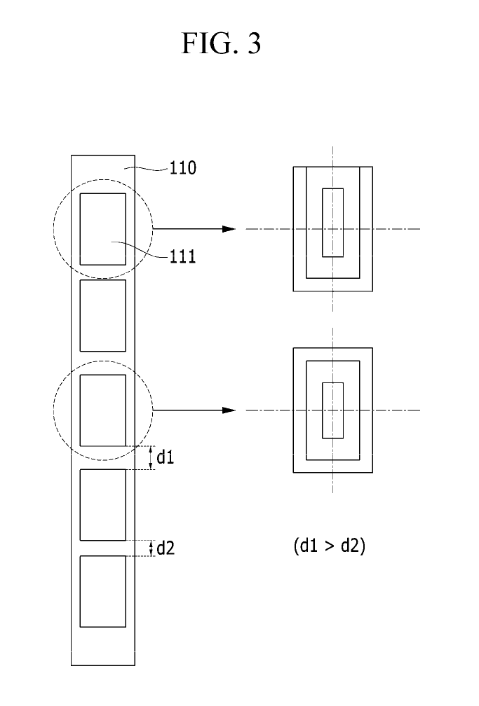

Hereinafter, a mask for depositing a thin film according to an exemplary embodiment of the present invention will be described with reference to FIGS. 1 to 3. FIG. 1 is a schematic perspective view illustrating a mask for depositing a thin film according to an exemplary embodiment of the present invention, FIG. 2 is a top plan view illustrating the mask for depositing a thin film according to the exemplary embodiment of the present invention, and FIG. 3 is a drawing illustrating a part of the mask according to the exemplary embodiment of the present invention.

Referring to FIG. 1, the mask for depositing a thin film according to the exemplary embodiment of the present invention includes a frame 30, and a plurality of mask strips 110 having opposing ends which are supported by the frame 30. That is, the plurality of mask strips 110 and the frame 30 collectively form a mask 100.

The frame 30 includes first supports 31 and 32, which are installed generally parallel to each other, and second supports 34 and 35 connected to ends of the first supports 31 and 32, respectively, to form a generally quadrangular opening 33. The second supports 34 and 35, which are installed in a direction generally parallel to the mask strips 110, may be formed of a material having elasticity, but are not essentially limited thereto. Also, the first supports 31 and 32 and the second supports 34 and 35 may be integrally formed.

The mask strips 110 may be supported by the frame 30 in a tension state, so that the frame 30 may have sufficient rigidity. Further, if a frame has a structure incurring no interference when a deposition target is in close contact with the mask 100, the frame may be applied to the frame 30.

The mask 100 includes at least one mask strip 110. The mask 100 may comprise the plurality of mask strips 110 fixed to the frame 30, and thus it is possible to prevent the mask strips from hanging over the frame due to weight of the mask strips, similar to the mask in the related art.

Further, according to the exemplary embodiment of the present invention, FIG. 2 illustrates that the predetermined mask strips 110 collectively form one mask 100. However, this is but one example, and the present invention is not limited thereto.

The plurality of mask strips 110 is formed in a generally rectangular plate shape, and has a plurality of pattern portions 111 for depositing at a predetermined interval in a longitudinal direction thereof (±y direction), and for each mask strip 110, a blocking portion is positioned around the pattern portion 111.

The plurality of mask strips 110 may be formed of a thin plate having a magnetic property, and may be formed of nickel or a nickel alloy as an example of the present invention, and further may be formed of an alloy of nickel and cobalt, which relatively readily forms a micro pattern and has desirable surface roughness.

In the plurality of mask strips 110, the pattern portion 111 of each mask strip 110 may be formed by using an electro forming method. According to the electro forming method, it is possible to achieve fine patterning and excellent surface smoothness. The pattern portion 111 for depositing the thin film may also be manufactured by an etching method, in such a manner that the pattern portion 111 for depositing the thin film may be formed by forming a photoresist layer having the same pattern as that of the pattern portion 111 on a thin plate, or attaching a film having the same pattern as that of the pattern portion 111 to a thin plate and then etching the thin plate.

Referring to FIGS. 1 and 2, in the mask strip 110 manufactured as described above, both ends of the mask strip 110 in the longitudinal direction of the mask strip 110 are fixed to the frame 30 in a state where predetermined tensile force is applied in the longitudinal direction (±y direction) of the mask strip 110. In this case, all of the pattern portions 111 for depositing of the mask strips 110 are disposed inside the opening 33 of the frame 30.

Affixing the plurality of mask strips 110 to the frame 30 may be done in various ways, such as laser welding and resistance heating welding, but the laser welding method may be used considering a change in accuracy and the like. In this case, the respective mask strips 110 may be welded so as to be arrayed while being spaced apart from each other by a predetermined distance.

When the mask 100 divided into the plurality of mask strips 110 is used as described above, a drop phenomenon due to weight of the mask strips 110 is improved as described above.

The pattern portion 111 included in the mask strip 110 forms a pattern by the deposition of the thin film. The pattern portion 111 may have an opening shape without a separate pattern as illustrated herein as an example of the present invention, or may include a stripe pattern (not illustrated). That is, a shape of the pattern portion 111 is not limited, and may be different according to the desired shape of the thin film.

The mask strip 110 includes the plurality of pattern portions 111, and each pattern portion 111 is spaced apart from each other by a predetermined interval. Also, according to the exemplary embodiment of the present invention, the intervals between the adjacent pattern portions 111 may be different as illustrated in FIG. 2, which is for the purpose of reducing shadow. In FIG. 2, a degree of “eccentricity” based on a center of the mask strip 110 is indicated by a size of an arrow. As the pattern portion 111 is far from the center of the mask strip 110, the pattern portion 111 is eccentric to the center, so that the interval or space between adjacent pattern portions 111 is narrow, and as the pattern portion 111 is closer to the center of the mask strip 110, the pattern portion 111 is less eccentric to the center, so that the interval between the adjacent pattern portions 111 is wider.

Particularly, referring to FIG. 3, when pattern portions 111 are directly under their corresponding deposition nozzles, no significant shadow occurs. However, for the case of a deposition nozzle positioned over one end of mask strip 110 and a pattern portion 111 positioned at the other end of mask strip 110, significant shadow can be produced.

Accordingly, the pattern portion 111 positioned at the outermost side is slightly moved toward the center (i.e. closer to its neighboring pattern portion 111 than those nearer the center of strip 110) according to the exemplary embodiment of the present invention, thereby reducing the generation of the shadow. That is, in a case of the plurality of pattern portions having the same interval, in order to reduce the generation of the shadow, the outer pattern portions, which would otherwise generate considerable shadow, are moved toward the center so as to reduce the spacing between pattern portions, and thus a deposition angle and the like are adjusted, thereby reducing the generation of the shadow. Accordingly, it is possible to form a pattern corresponding to the fine pattern portion 111, thereby providing an organic light emitting diode display with high resolution.

More particularly, the interval between the adjacent pattern portions 111 near the center of one mask strip 110 may be increased. A distance between two adjacent pattern portions 111 close to the center of mask strip 110 is larger than the interval between two adjacent pattern portions 111 far from the center. The reason is that the pattern portions 111 positioned far from the center move significantly toward the center. Shadow having the largest area is formed in the pattern portion 111 positioned at the outermost side based on the center of the mask strip 110, and in order to reduce the shadow, the pattern portion 111 positioned at the outermost side is moved most. Accordingly, a degree of movement of the pattern portion 111 positioned next to the outermost pattern portion 111 may be slightly smaller than that of the outermost pattern portion 111. Accordingly, a degree of the movement of the pattern portion 111 is changed according to a degree of the distance of the pattern portion 110 from the center of the mask strip 110.

Further, the distance between adjacent pattern portions 111 may be symmetric with respect to the center of the mask strip 110. The mask strip 110 according to the exemplary embodiment of the present invention may include 5 or 7 pattern portions 111, which may be symmetric with respect to the center of the mask strip 110.

Further, in the present specification, only the exemplary embodiment, in which one mask strip 110 includes the 5 or 7 pattern portions 111, is illustrated, but the mask strip 110 is not limited thereto, and may include any number of pattern portions.

FIGS. 2 and 3 illustrate the mask 100 for depositing the thin film performing a deposition in a straight direction, and thus the intervals of the adjacent pattern portions 111 based on the center of the mask strip 110 in one direction are different. An interval d1 between the pattern portions 111 close to the center is slightly larger, and the interval d2 between adjacent pattern portions 111 shrinks with distance from the center. The reason is that the pattern portion is moved much toward the center compared to a case where the distance between the pattern portions is equal. The interval may be adjusted according to a degree of the space of the pattern portion from the center and a size of the generated shadow.

To summarize, according to embodiments of the present invention, in order to reduce the shadow generated according to deposition angle, the pattern portions may be moved toward the center of the mask or the mask strip according to their distance from the center, with those farther from the center moved to a greater degree than those closer to the center.

In the present specification, only the plurality of pattern portions 111 having different distances in a straight direction (e.g., directions x or y) has been described, but the present invention is not limited thereto, and it is possible to adjust the distance between the adjacent pattern portions 111 in response to the deposition direction, or any desired direction.

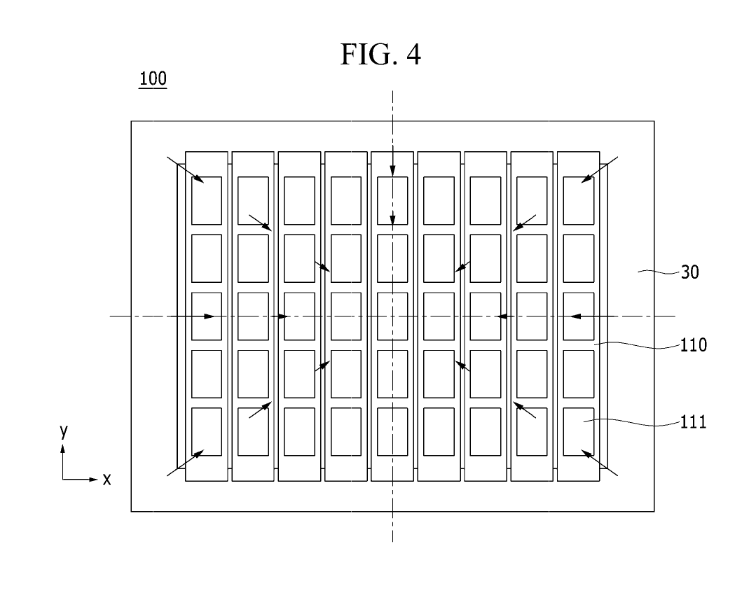

FIG. 4 is a top plan view illustrating a mask according to another exemplary embodiment of the present invention, and only differences from the previous exemplary embodiment of the present invention will be described.

Particularly, referring to FIG. 4, a mask 100 for depositing a thin film performing deposition in a radial direction is illustrated. Accordingly, distances between pattern portions 111 adjacent in a radial direction based on the center of the mask 100 itself including all of a plurality of mask strips 110, may vary by distance from this center.

That is, positions of the pattern portions 111 with respect to the radial distance from the overall center of the mask 100 are adjusted. Particularly, the pattern portions 111 inwardly lean based on the center of the radius. The pattern portions 111 are moved toward the center of the mask 100 compared to a case where the distance between the pattern portions 111 is uniform, and a degree of movement of the pattern portion may be adjusted in order to reduce shadow. For example, the pattern portion 111 may be moved by a distance corresponding to a half of a maximum degree of generation of shadow.

In FIG. 4, a degree of eccentricity of each pattern portion 111 with respect to the center of the mask 100 is indicated by an arrow, and represents a degree of relative eccentricity.

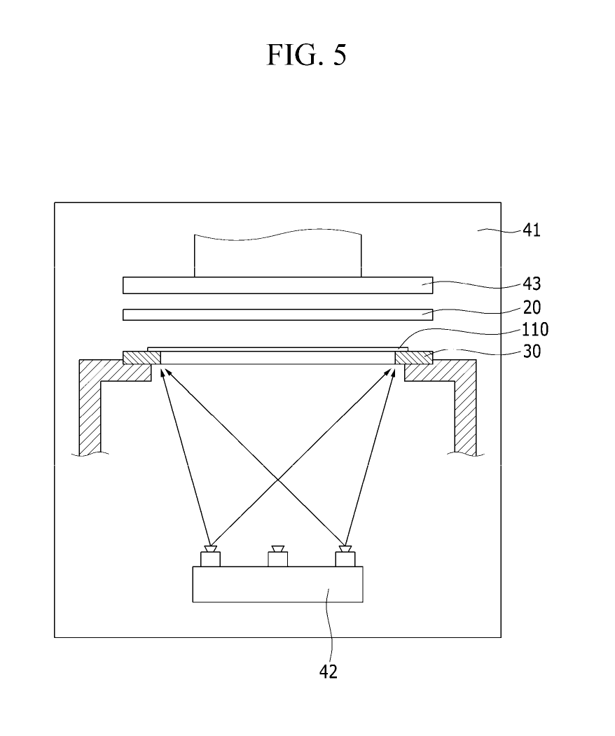

Hereinafter, a deposition device using the mask for depositing the thin film will be described. FIG. 5 is a side view illustrating a deposition device using the mask for deposition according to the exemplary embodiment of the present invention.

The masks for depositing the thin film according to the exemplary embodiments are mounted on the deposition device illustrated in FIG. 5 to perform deposition.

Referring to FIG. 5, in order to deposit a thin film of an organic light emitting diode display (for example, an intermediate layer including light emitting portions emitting light of red, green, and blue) by using the mask 100, the frame 30 with the mask strips 110 is installed at a position corresponding to a thin film deposition vessel 42 installed at a vacuum chamber 41.

Next, a target 20, on which a thin film and the like are to be deposited, is positioned on the frame 30. Further, a fixing unit 43 is positioned on the target 20, so that the mask 100 is in close contact with the target 20 on which the thin film and the like are to be formed. In this state, a material included in the thin film deposition vessel 42 is deposited on the target 20 through an operation of the thin film deposition vessel 42.

Particularly, in this case, a distance between the thin film deposition vessel 42 and the mask 100 may be slightly long. When the distance is long, efficiency of the deposition material may be slightly decreased, but an angle at which the deposition material is incident is changed (and generally reduced), so that generation of shadows may be reduced.

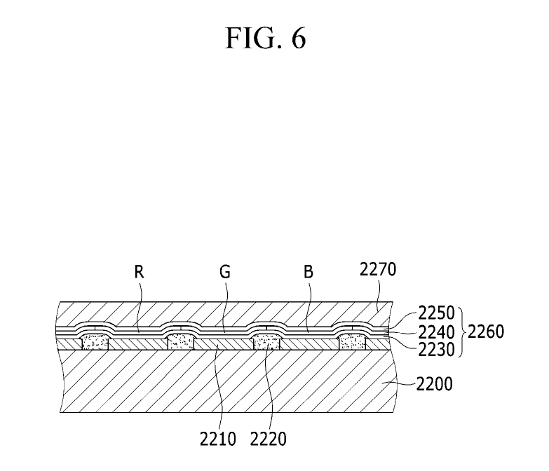

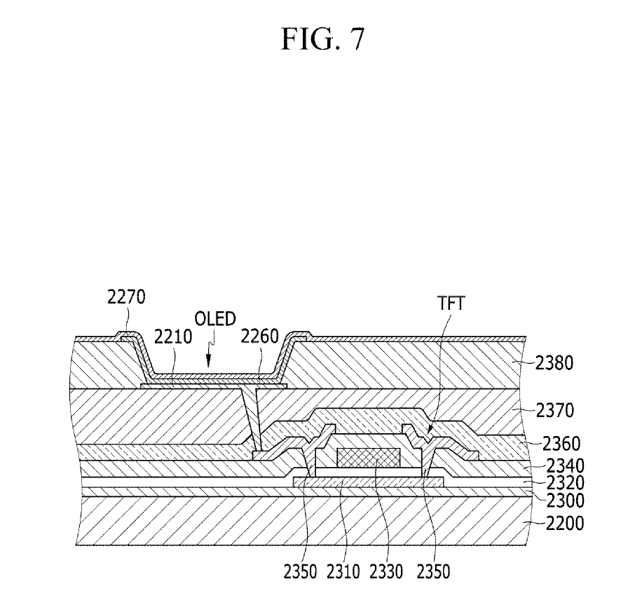

Hereinafter, an organic light emitting diode display manufactured by using the mask for depositing the thin film according to the exemplary embodiment of the present invention will be described. FIG. 6 is a cross-sectional view illustrating an organic light emitting diode display according to an exemplary embodiment of the present invention, and FIG. 7 is a cross-sectional view illustrating the organic light emitting diode display according to this exemplary embodiment of the present invention.

FIG. 6 illustrates an example of a passive matrix type organic light emitting diode display. Here, a first electrode 2210 is formed on a substrate 2200 in a stripe pattern, and an organic layer 2260 including a light emitting layer, as well as a second electrode 2270, are sequentially formed on the first electrode 2210. Insulating layers 2230 and 2250 may be further interposed between lines of the electrodes 2210 and 2270, and the second electrode 2270 may be formed in a pattern orthogonal to a pattern of the first electrode 2210.

In the meantime, organic light emitting layers 2240 in the organic layer 2260 are formed of red R, green G, and blue B organic light emitting layers to implement various colors, and may be formed by using the masks including the plurality of pattern portions according to the aforementioned exemplary embodiments.

The first electrode 2210 serves as an anode electrode, and the second electrode 2270 serves as a cathode electrode. Polarities of the first electrode 2210 and the second electrode 2270 may be opposite to each other as a matter of course.

FIG. 7 illustrates an example of one sub-pixel of an active matrix type (AM type) organic light emitting diode display. Sub-pixels in FIG. 7 have at least one thin film transistor and an organic light emitting diode OLED, which is a self-emitting element.

The thin film transistor is not limited to the structure illustrated in FIG. 7, and the number and the structure thereof may be variously changed. The AM type organic light emitting diode display will be described in detail below.

A buffer layer 2300 formed of SiO₂, SiNx, and the like is formed on a substrate 2200, and the aforementioned thin film transistor is formed on the buffer layer 2300.

The thin film transistor includes a semiconductor active layer 2310 formed on the buffer layer 2300, a gate insulating layer 2320 formed so as to cover the active layer 2310, and a gate electrode 2330 on the gate insulating layer 2320. An interlayer insulating layer 2340 is positioned so as to cover the gate electrode 2330, and source and drain electrodes 2350 are positioned on the interlayer insulating layer 2340. The source and drain electrodes 2350 are in respective contact with a source region and a drain region of the active layer 2310 by contact holes positioned in the gate insulating layer 2320 and the interlayer insulating layer 2340. The active layer 2310 may be formed from an inorganic semiconductor or an organic semiconductor.

A passivation layer 2360 formed of SiO2, SiNx, and the like is positioned on the source and drain electrodes 2350, and a planarization film 2370 formed of acryl, polyimide, and the like is positioned on the passivation layer 2360. Although not illustrated in the drawing, at least one capacitor is connected to the thin film transistor.

In the meantime, an organic light emitting diode OLED is in contact with the source and drain electrodes 2350 via a connection to the first electrode 2210, which is the anode electrode of the organic light emitting diode OLED. The first electrode 2210 is positioned on the planarization film 2370, and a pixel defining layer 2380 is positioned so as to partially cover the first electrode 2210. Further, after a predetermined opening is formed in the pixel defining layer 2380, the organic light emitting diode OLED is formed.

The organic light emitting diode OLED displays predetermined image information by emitting light of red, green, and blue (or any other set of colors) according to a flow of a current, and includes a first electrode 2210 connected to the source and drain electrodes 2350 of the thin film transistor to receive plus power from the source and drain electrodes 2350, a second electrode 2270 provided so as to cover the entire pixels to supply minus power, and an organic layer 2260 disposed between the first electrode 2210 and the second electrode 2270 to emit light.

In the AM type organic light emitting diode display, an organic light emission layer EMI of the organic layer 2260 is patterned by using the masks for depositing the thin film according to the aforementioned exemplary embodiments, thereby implementing a display with high accuracy.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims. Various features of any embodiments may be mixed and/or matched in any manner, to produce further embodiments contemplated by the invention.

<Description of symbols>

| | |
|---|---|
| 30: Frame | 31, 32: First support |
| 33: Opening | 34, 35: Second support |
| 41: Vacuum chamber | 42: Thin film deposition vessel |
| 43: Fixing unit | 100: Mask |
| 110: Mask strip | 111: Pattern portion |

What is claimed is:

1. A mask for depositing a thin film, comprising:
mask strips each including a plurality of pattern portions disposed end to end along one direction; and
a frame on which the mask strips are positioned,
wherein intervals between adjacent ends of adjacent pattern portions differ from each other according to distance from a predetermined location.

2. The mask of claim 1, wherein:
a distance between the adjacent ends of adjacent pattern portions decreases with distance from a center of the mask strip.

3. The mask of claim 2, wherein:
the number of mask strips is plural.

4. The mask of claim 1, wherein:
the intervals between the adjacent pattern portions of each mask strip are collectively positioned so as to be symmetric with respect to a center of the each mask strip.

5. The mask of claim 1, wherein:
each mask strip has a predetermined tension.

6. The mask of claim 1, wherein:
each mask strip includes nickel or a nickel alloy.

7. The mask of claim 3, wherein:
each mask strip of the plurality of mask strips is welded to the frame.

8. The mask of claim 7, wherein:
each mask strip of the plurality of mask strips is affixed to the frame by laser welding.

9. The mask of claim 1, wherein:
the intervals between the adjacent pattern portions of each mask strip are collectively positioned so as to be radially symmetric with respect to a center of the collective mask strips.

10. A method of manufacturing an organic light emitting diode display, comprising:
forming a first electrode;
forming an organic light emitting layer on the first electrode by using a mask for depositing a thin film; and
forming a second electrode on the organic light emitting layer,
wherein the mask for depositing the thin film includes:
mask strips each including a plurality of pattern portions disposed end to end along one direction; and
a frame on which the mask strips are positioned, and
wherein intervals between adjacent ends of adjacent pattern portions differ from each other according to distance from a predetermined location.

11. The method of claim 10, wherein:
a distance between the adjacent ends of adjacent pattern portions decreases with distance from a center of the mask strip.

12. The method of claim 10, wherein:
the number of mask strips is plural.

13. The method of claim 9, wherein:
the intervals between the adjacent pattern portions of each mask strip are collectively positioned so as to be symmetric with respect to a center of the each mask strip.

14. The method of claim 10, wherein:
each mask strip has a predetermined tension.

15. The method of claim 10, wherein:
each mask strip includes nickel or a nickel alloy.

16. The method of claim 12, wherein:
each mask strip of the plurality of mask strips is welded to the frame.

17. The method of claim 16, wherein:
each mask strip of the plurality of mask strips is affixed to the frame by laser welding.

18. The method of claim 10, wherein the intervals between the adjacent pattern portions of each mask strip are collectively positioned so as to be radially symmetric with respect to a center of the collective mask strips.

19. An organic light emitting diode display manufactured according to claim 10.
